(19) United States
(12) Patent Application Publication
(10) Pub. No.: US 2009/0323287 A1
(43) Pub. Date: Dec. 31, 2009

(54) Integrated Circuit Cooling Apparatus for Focused Beam Processes

(76) Inventor: Joseph Martin Patterson, Carlsbad, CA (US)

Correspondence Address: LAW OFFICE OF GERALD MALISZEWSKI, P.O. BOX 270829, SAN DIEGO, CA, 92198-2829, US

(21) Appl. No.: 12/330,376

(22) Filed: Dec. 8, 2008

Related U.S. Application Data
(63) Continuation-in-part of application No. 12/242,545, filed on Sep. 30, 2008.
Application No. 12/242,545 is a continuation-in-part of application No. 12/145,566, filed on Jun. 25, 2008.

(51) Int. Cl. H05K 7/20

(52) U.S. Cl. 361/709

(57) ABSTRACT

A fixture and method are provided for cooling an IC in the performance of focused beam processes. The method provides a holding/cooling fixture with thermal electric (TE) jaws having an IC interface surface and a heatsink interface. An IC die is secured between the IC interface surfaces of the jaws. Electrical energy is supplied to the TE jaws, creating a negative temperature differential between the IC interface and heatsink interfaces. As a result, the IC die is cooled. A focused beam is applied to a local region of the IC die. Some examples of the focused beam include a focused ion beam (FIB), scanning electron microscope (SEM), E-beam, or a laser scanning microscope (LSM). The focused beam heats the local region of the IC, while the bulk of the IC remains cooled. Typically, each TE jaw includes a plurality of TE elements thermally connected in series.

### RELATED APPLICATIONS

This application is a Continuation-in-Part of a pending application entitled, NON-DESTRUCTIVE LASER OPTICAL INTEGRATED CIRCUIT PACKAGE MARKING, invented by Joseph Patterson, Ser. No. 12/242,545, filed Sep. 30, 2008, attorney docket No.: applied_{—}278;

which is a Continuation-in-Part of a pending application entitled, LASER OPTICAL PATHWAY DETECTION IN INTEGRATED CIRCUIT PACKAGING, invented by Joseph Patterson, Ser. No. 12/145,566, filed Jun. 25, 2008, attorney docket No.: applied_{—}254. Both these applications are incorporated herein by reference.

### BACKGROUND OF THE INVENTION

1. Field of the Invention

This invention generally relates to integrated circuit (IC) fabrication and, more particularly, to a method for cooling an IC during focused beam inadvertent localized heating processes.

2. Description of the Related Art

IC devices are formed from a die of active semiconductor devices. The die can be mounted in a hybrid circuit, printed circuit board (PCB), or a package. For environmental protection, the die may be covered by a passivation layer. However, a package is more typically used since it also dissipates heat and provides a lead system for electrical connections. There are many different types of packages including through-hole, surface mount device (SMD) dual/quad, and SMD area array packages.

FIGS. 1A and 1B are perspective views of a dual in-line package (DIP) and an IC die without a package, respectively (prior art). It is common for a package body or lead frame 100 to have a die attach area 102. The die 106 has electrical contact pads on its top surface. Inner leads 108 connect pads on die top surface to outer leads or lead frames 110. Once the inner leads are bonded to the lead frames, the package is sealed with ceramic, in a metal can, or in a polyimide. Epoxy resins are also a common choice. Glass beads are commonly mixed in with the epoxy to reduce strain in the epoxy film during changes in temperature.

Optical beam induced current (OBIC) is a semiconductor analysis technique performed using laser signal injection. The technique induces current flow in the semiconductor sample through the use of a laser light source. This technique is used in semiconductor failure analysis to locate buried diffusion regions, damaged junctions, and gate oxide shorts.

The OBIC technique may be used to detect the point at which a focused ion beam (FIB) milling operation in bulk silicon of an IC must be terminated. This is accomplished by using a laser to induce a photocurrent in the silicon, while simultaneously monitoring the magnitude of the photocurrent by connecting an ammeter to the device's power and ground. As the bulk silicon is thinned, the photocurrent increases as the depletion region of the well to substrate junction is reached. FIB milling operations are terminated in a region below the well depth, so the device remains operational.

Focused beams are also used to inspect an IC. However, the energy imparted by a focused beam may unintentionally heat, mill, or sputter a sample IC surface. Conventionally, ICs are fabricated at relatively high process temperatures, and the materials used are able to withstand any unintended heating effects associated with focused beam inspection processes.

The latest generation of integrated circuits contains dielectric films, such as low-k dielectrics that contain organic components. These dielectrics are much more sensitive to heating by an electron beam, ion beam, or laser beam of microscope, than conventional dielectric materials, such as silicon oxide, silicon nitride, or silicon oxynitride. Delamination, shrinkage, and decomposition of the films may occur due to concentrated heating from the energy in the beams delivered to the sample. This problem is enhanced during examination of IC cross-sections. The latest generation of electron beam microscopes is designed to have improved imaging resolution at low beam accelerating potentials, which may minimize potential damage. However, scanning electron microscopes (SEMs) still have the best image resolution at high beam voltage, so it is still advantageous to examine a sample with very small features using higher beam voltages. Unfortunately, the damaging energy delivered to a sample by the E-beam is proportional to the square of the beam voltage.

The highest temperature to which a finished integrated circuit may be exposed to during fabrication after the deposition of organic dielectric films is about 400° centigrade (C). Thus, localized heating during SEM examination must be kept below that temperature.

Cooling or freezing many types of samples is known as a means of protection against localized heating operations. For example, biological samples may be prepared for electron beam examination by removing water and volatiles from the sample by critical point drying or freeze drying, before putting exposing them to localized heating in a microscope chamber. A focused ion beam can be used with cryogenically frozen samples in a suitably equipped instrument, for example, permitting cross-sectional analysis of samples containing liquids or fats, such as biological samples, pharmaceuticals, foams, inks, and food products.

It would be advantageous if a method existed to minimize the likelihood of damaging an IC during focused beam operations that generate localized heating.

### SUMMARY OF THE INVENTION

A method and fixture are presented that permits the performance of electron beam, focused ion beam, or infrared (IR) laser beam examinations on integrated circuits containing sensitive materials, such as dielectric films containing organ compounds. The fixture is a multi-stage thermal electric device capable of cooling an IC sample 100 to 150 degrees centigrade below room temperature, thus preventing dielectric films from reaching damaging temperatures during focused beam operations, such as (electron-beam) E-beam, focused ion beam (FIB), or laser examination.

Accordingly, a method is provided for cooling an integrated circuit IC in the performance of focused beam processes. The method provides a holding/cooling fixture with thermal electric (TE) jaws having an IC interface surface and a heatsink interface. An IC die, or IC die embedded in an IC package, is secured between the IC interface surfaces of the jaws. Electrical energy is supplied to the TE jaws, creating a negative temperature differential between the IC interface and heatsink interfaces. As a result, the IC die is cooled. A focused beam is applied to a local region of the IC die. Some examples of the focused beam include a FIB, scanning electron microscope (SEM), E-beam, or a laser scanning microscope (LSM). The focused beam heats the local region of the IC, while the bulk of the IC remains cool.

Typically, each TE jaw includes a plurality of TE elements thermally connected in series. The negative temperature differential between the IC interface surfaces of the jaws and heatsink is created as a result of a negative temperature differential across each TE element, which creates an overall temperature differential that is the sum of the plurality of TE elements. The TE elements have thermal interface surfaces that progressively increase in size from the IC interface surface to the heatsink interface surface.

Additional details of the above-described method and a fixture for holding and cooling an IC in the performance of focused beam processes, are provided below.

### BRIEF DESCRIPTION OF THE DRAWINGS

FIGS. 1A and 1B are perspective views of a dual in-line package (DIP) and an IC die without a package, respectively (prior art).

FIG. 2 is a partial cross-sectional view of a fixture for holding and cooling an IC in the performance of focused beam processes.

FIG. 3 is a schematic diagram of a TE element.

FIGS. 4A and 4B are plan and cross-sectional views, respectively, of an exemplary embodiment of the fixture of FIG. 2.

FIG. 5 is a plan view of another exemplary embodiment of the fixture of FIG. 2.

FIG. 6 is a partial cross-sectional view of yet another exemplary embodiment of the fixture of FIG. 2.

FIG. 7 is a flowchart illustrating a method for cooling an IC in the performance of focused beam processes.

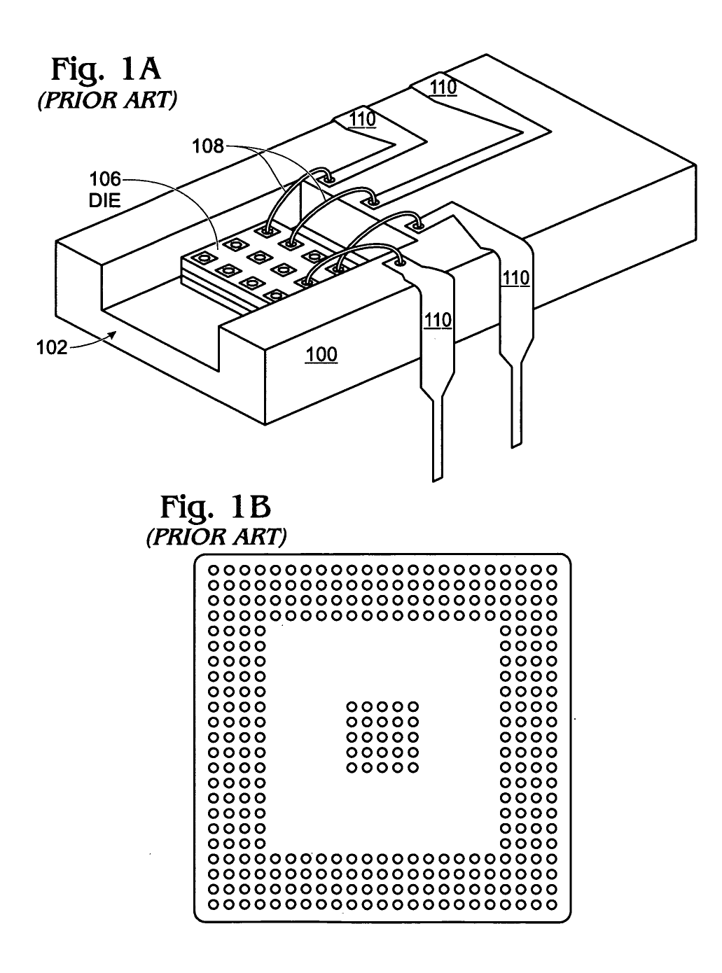

### DETAILED DESCRIPTION

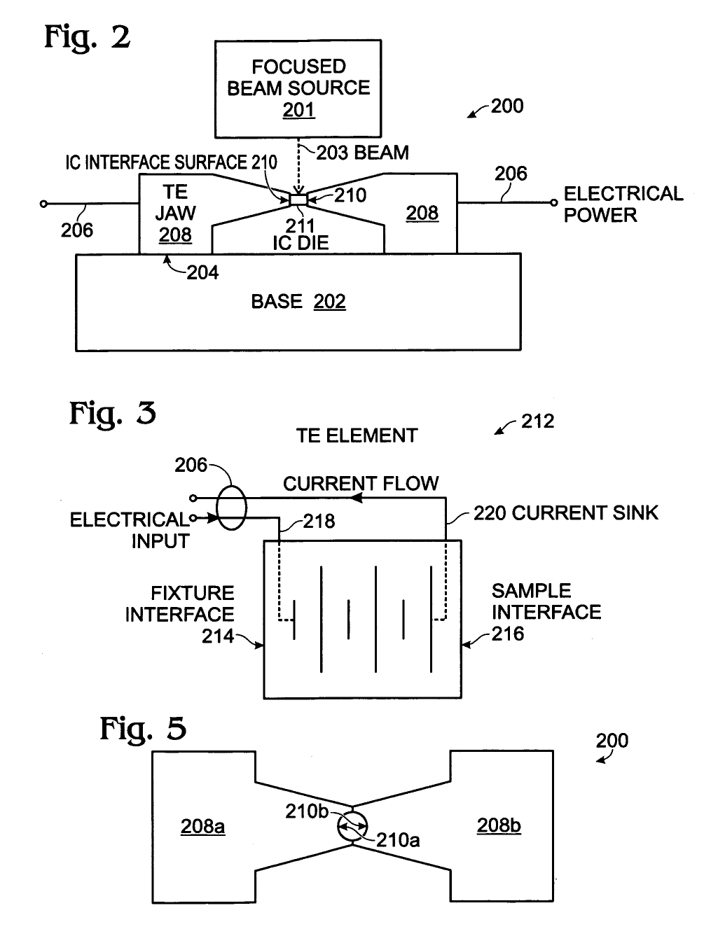

FIG. 2 is a partial cross-sectional view of a fixture for holding and cooling an IC in the performance of focused beam processes. The fixture 200 comprises a base 202 with a heatsink interface 204. Reference designator 201 represents the focused beam source and reference designator 203 represents the focused beam. Some examples of focused beams include charged beam sources, such as a focused ion beam (FIB), scanning electron microscope (SEM), or E-beam. Another example of a focused beam is a laser scanning microscope (LSM). However, this list of sources is not exhaustive, and the fixture has application to any process capable of heating a localized region of a sample, regardless of the heat source.

Electron beam (E-beam) processing uses a high-energy electron beam accelerator. Typically, the design is similar to that of a cathode ray television. The scanning electron microscope (SEM) is a type of electron microscope that images the sample surface by scanning it with a high-energy beam of electrons in a raster scan pattern. The electrons interact with the atoms that make up the sample producing signals that contain information about the sample's surface topography, composition and other properties such as electrical conductivity. The signals require the use of a specialized detector. A SEM can produce very high-resolution images of a sample surface, revealing details about 1 to 5 nm in size. LSM is a line of confocal laser scanning microscopes produced by the Zeiss company.

A FIB resembles a scanning electron microscope, except that the SEM uses a focused beam of electrons to image a sample, a FIB instead uses a focused beam of gallium ions. The FIB can also be incorporated in a system with both electron and ion beam columns, allowing the same feature to be investigated using either of the beams. These ions are then accelerated to an energy of 5-50 keV (kiloelectronvolts), and then focused onto the sample by electrostatic lenses. A modern FIB can deliver tens of nanoamps of current to a sample, or can image the sample with a spot size on the order of a few nanometers.

The fixture 200 has an electrical interface on line 206, to provide power to a thermal-electric (TE) jaws 208. The TE jaws 208 are mounted on the base heatsink interface 204, and have IC interface surfaces 210 to secure an IC die 211, each TE jaw 208 creates a negative temperature differential between an IC interface surface 210 and the heatsink 204 interface in response to energy supplied at the electrical interface on line 206. That is, when electrical power is applied to a TE jaw 208, the IC interface surface decreases in temperature while the heatsink interface increases in temperature.

FIG. 3 is a schematic diagram of a TE element. Each TE jaw includes at least one TE element 212 with two thermal interfaces. The thermal interface closest to the heatsink interface (FIG. 2-204) is the fixture interface 214, and the thermal interface nearest the IC die is the sample interface 216. The TE element 212 is defined as an element that relies upon the Peltier effect to convert electrical current into temperature, and a series of thermocouples (a thermopile) exhibiting the Seebeck effect, which is the result of two Peltier electromotive forces (emfs) and two Thomson emfs.

When the input voltage is high, current flows from an electrical input on line 218 to the current sink on line 220. Thermal energy is carried by the electrons from the negative side to the positive side. If the fixture interface 214 is held at a constant temperature (by heat-sinking), the sample interface 216 decreases in temperature. Note: lines 218 and 220 are subcomponents of the electrical interface on line 206.

The performance of thermal electric devices is based upon two effects: the Peltier effect and the Thomson effect. The Peltier effect defines the results when a single junction, made from two different materials, is joined and a current is sent through the junction while the thermal electric device ends are maintained at constant temperature. Under these conditions a heat flow takes place between the junction and it surroundings. The amount of Peltier heat transferred at any junction is proportional to the current through the junction and that the transfer reverses direction when the direction of the current is reversed. Such a junction is a source within which electrical energy is converted to heat, or heat is converted to electrical energy.

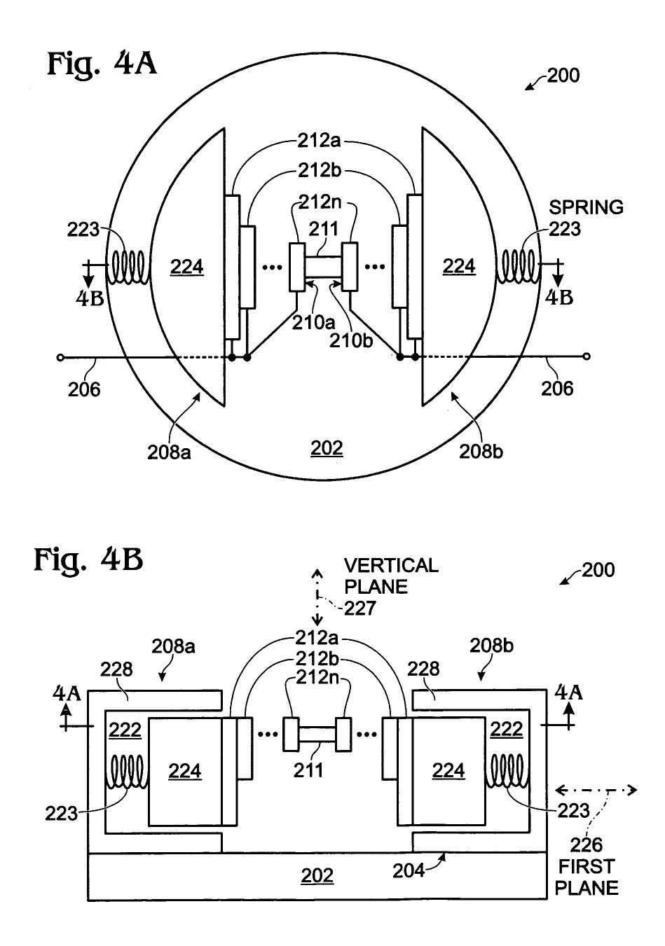

FIGS. 4A and 4B are plan and cross-sectional views, respectively, of an exemplary embodiment of the fixture of FIG. 2. As shown, a first jaw 208a and a second jaw 208b are mounted on the base heatsink interface 204. Each jaw 208 includes a cavity 222 with spring (223)-loaded piston 224, moveable in a first plane 226, which for the purposes of simplicity may be referred to as the horizontal plane. However, it should be understood that the term “horizontal” is a relative term used only for convenience. At least one TE element 212 is interposed between the 224 piston and the IC interface surface 210. (n) TE elements are depicted, where n is not limited to any particular value.

In this two-jaw aspect of the fixture, the first jaw IC interface surface 210a is symmetrically opposed to the second jaw IC interface 210b. Typically, the first and second jaw IC interface surfaces 210a and 210b are parallel to a common vertical plane 227. Again, the term “vertical” is relative and used for simplicity. In other aspects not shown, the IC interface surfaces may be shaped to conform to a particular sample (e.g., IC die or IC die package) shape.

Each jaw 208 includes a plurality of TE elements 212 thermally connected in series, creating an overall temperature differential between the IC interface surface 210 and the heatsink interface 204 that is the sum of the plurality of TE element elements. Typically, each TE element 212 in the series has thermal interface surfaces (i.e. the fixture and sample thermal interfaces) that progressively increase in size from the IC interface surface 210 to the piston 224.

Generally, the IC interface surfaces 210 can be enabled to provide a temperature of less than −20° C. This temperature value assumes an ambient base 202 temperature of approximately 25° C. However, with enough TE elements, large enough TE thermal interfaces, and sufficient electrical current, it is possible to create IC interface surface temperatures that are 100 to 150 degrees lower than ambient room temperature.

Generally, in all the embodiments described herein, opposing jaws have matching temperature coefficients, as related to the expansion/contraction of the jaws and the movement of the IC interface surfaces as the temperature changes. With respect to the fixture of FIGS. 4A and 4B, the first jaw IC interface surface 210a has a first coefficient of temperature expansion, and the second jaw IC interface surface 210b has the first coefficient of temperature expansion. Since the jaws are opposing, any thermal expansion/contraction is self-canceling, and the position of IC die 211 remains constant.

If a charged beam is used, each jaw cavity 222 has a top surface 228 that shields a charged beam from fields generated by current flow through the TE elements. Unless shielded, the fields distort the focus of the charged beam, causing diffusion or misdirection of the beam.

FIG. 5 is a plan view of another exemplary embodiment of the fixture of FIG. 2. In this aspect, the first and second jaw IC interface surfaces 210a and 208b are vertical (in cross-section, not shown), having a semi-circular shape in a plan view. In other aspects not shown, the IC interface surfaces can be shaped to cool some portions of the IC die more than other portions.

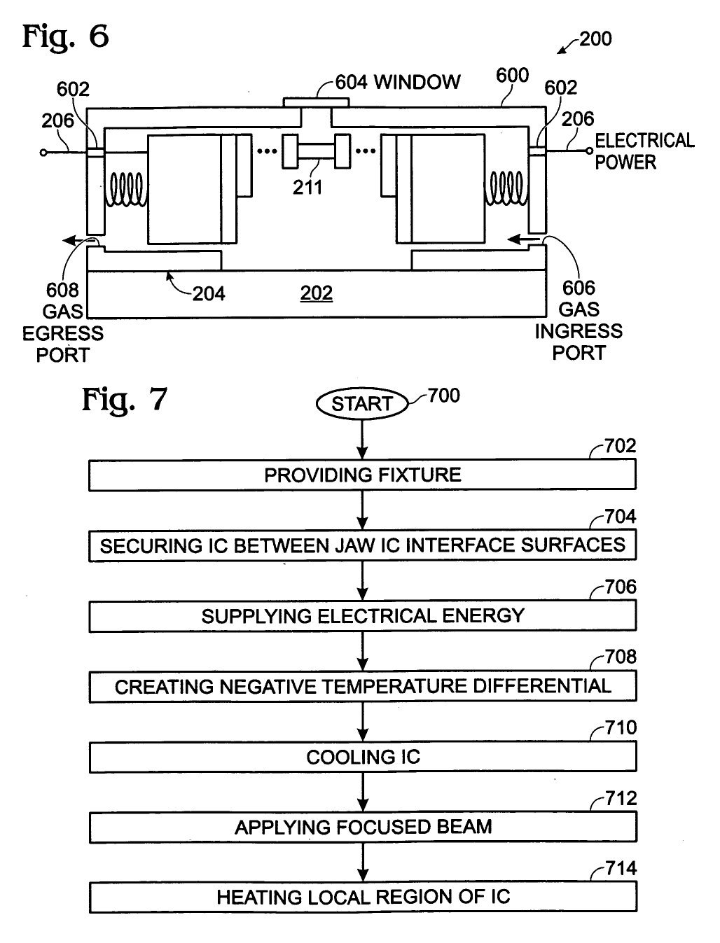

FIG. 6 is a partial cross-sectional view of yet another exemplary embodiment of the fixture of FIG. 2. This aspect includes an environmental chamber 600 surrounding the fixture 200 having a port 602 for the electrical interface 206, and a focused beam window 604 overlying the IC die 211. The environmental chamber 600 may also have a gas ingress port 606 and a gas egress port 608. The fixture in the environmental chamber generally conforms to the embodiment of FIG. 4B. However, it should be understood that an environmental chamber can be formed around a variety of fixture styles and shapes.

### Functional Description

As shown in FIG. 6, the fixture can be placed inside a vacuum chamber 600 on a base 202, which might be a SEM stage. The fixture jaws are multi-stage TE element coolers arranged in an opposing clamping configuration to hold the sample IC mechanically, and to provide good thermal contact between the sample and the TE elements. The fixture also provides adequate heat sinking to the SEM stage for the “hot” ends (i.e. the fixture interfaces) of the TE elements.

Two features of the fixture are its symmetry, as shown in the examples of FIGS. 4A and 5, and its shielding, as shown in FIG. 4B. All components of the fixture are symmetrical about the center of the base 202, which may also be referred to as a stage or wafer holding chuck, so that movement due to thermal expansion is minimal, with the sample held constant in a central position. Minimizing movement during high magnification examinations is critical.

The thermal electric elements may be operated with a substantial direct current and the resulting electric fields can displace electron and ion beams. Therefore, metallic shielding of the TE elements is necessary if a charged beam is used, in a manner that permits access to the sample.

As noted above, the latest generation of ICs contains dielectric films, such as low-k dielectrics, which contain organic components that are much more sensitive to heating by the electron beams, ion beams, or the laser beam of microscopes. Overheating causes delamination, shrinkage, and decomposition of the films due to concentrated heating from the energy in the beams delivered to the sample. The highest temperatures to which a typical IC is exposed during fabrication, after the deposition of organic dielectric films, is about 400 centigrade. The heating of the IC during SEM examination should be kept below that temperature. A multi-stage thermal electric device fixture described herein can cool the sample 100 to 150 degrees centigrade below room temperature, preventing the dielectric films from reaching damaging temperatures during E-beam, FIB, or laser examination.

FIG. 7 is a flowchart illustrating a method for cooling an IC in the performance of focused beam processes. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 700.

Step 702 provides a holding/cooling fixture with TE jaws having an IC interface surface and a heatsink interface. The embodiments described in FIGS. 2 through 6 are examples of such a fixture. As shown in FIG. 4B, the cooling fixture may have TE jaws with spring-loaded opposing vertical IC interface surfaces.

Step 704 secures an IC die between the IC interface surfaces of the jaws. Note: the IC die may be embedded in an IC package, in which case it could be said that the IC package is secured between IC interface surfaces. Step 706 supplies electrical energy to the TE jaws. In response to the electrical energy, Step 708 creates a negative temperature differential between the IC interface and heatsink interfaces. Step 710 cools the IC die. For example, the IC die may be cooled to a temperature of less than −20° C. In one aspect, the IC die is cooled between TE jaws having equal and opposing coefficients of temperature expansion.

Step 712 applies a focused beam to a local region of the IC die. As noted above, some examples of a focused beam include a charged beam source, such as a FIB, SEM, or E-beam. A LSM is another example of a focused beam. Step 714 heats the local region of the IC while the bulk of the IC remains cooled.

In one aspect, Step 702 provides each TE jaw with a plurality of TE elements thermally connected in series. Then, creating the negative temperature differential between the IC interface surfaces of the jaws and heatsink in Step 708 includes creating a negative temperature differential across each TE element, resulting in an overall temperature differential that is the sum of the plurality of TE elements. As shown in FIG. 4B, Step 702 may provide TE elements with thermal interface surfaces that progressively increase in size from the IC interface surface to the heatsink interface surface.

A fixture and method have been provided for cooling an IC in the performance of focused beam processes. Examples of focused beam types, structural components, and applications have been given to illustrate the invention. However, the invention is not limited to merely these examples. Other variations and embodiments of the invention will occur to those skilled in the art.

We claim:

1. A method for cooling an integrated circuit (IC) in the performance of focused beam processes, the method comprising:
providing a holding/cooling fixture with thermal electric (TE) jaws having an IC interface surface and a heatsink interface;
securing an IC die between the IC interface surfaces of the jaws;
supplying electrical energy to the TE jaws;
in response to the electrical energy, creating a negative temperature differential between the IC interface and heatsink interfaces; and,
cooling the IC die.

2. The method of claim 1 further comprising:
applying a focused beam to a local region of the IC die, the focused beam selected from a group consisting of charged beam sources including a focused ion beam (FIB), scanning electron microscope (SEM), E-beam, and a laser scanning microscope (LSM); and,
heating the local region of the IC.

3. The method of claim 1 wherein providing the cooling fixture with TE jaws includes providing TE jaws having spring-loaded opposing vertical IC interface surfaces.

4. The method of claim 1 wherein providing the cooling fixture with TE jaws includes providing each TE jaw with a plurality of TE elements thermally connected in series; and,
wherein creating the negative temperature differential between the IC interface surfaces of the jaws and heatsink includes:
creating a negative temperature differential across each TE element; and,
creating an overall temperature differential that is the sum of the plurality of TE elements.

5. The method of claim 4 wherein providing each TE jaw with a plurality of TE elements includes providing TE elements having thermal interface surfaces that progressively increase in size from the IC interface surface to the heatsink interface surface.

6. The method of claim 1 wherein cooling the IC die includes cooling the IC to a temperature of less than −20° C.

7. The method of claim 1 wherein cooling the IC die includes cooling the IC die between TE jaws having equal and opposing coefficients of temperature expansion.

8. A fixture for holding and cooling an integrated circuit (IC) in the performance of focused beam processes, the fixture comprising:
a base with a heatsink interface;
an electrical interface; and,
a thermal-electric (TE) jaws mounted on the base heatsink interface, having IC interface surfaces to secure an IC die, each TE jaw creating a negative temperature differential between a IC interface surface and the heatsink interface in response to energy supplied at the electrical interface.

9. The fixture of claim 8 wherein the TE jaws includes a first jaw and a second jaw mounted on the base heatsink interface, each jaw including a cavity with spring-loaded piston, moveable in a horizontal plane, and at least one TE element interposed between the piston and the IC interface surface.

10. The fixture of claim 9 wherein a first jaw IC interface surface is symmetrically opposed to a second jaw IC interface.

11. The fixture of claim 10 wherein the first and second jaw IC interface surfaces are parallel to a common vertical plane.

12. The fixture of claim 10 wherein the first and second jaw IC interface surfaces are vertical in cross-section, having a semi-circular shape in a plan view.

13. The fixture of claim 10 wherein each jaw includes a plurality of TE elements thermally connected in series, creating an overall temperature differential between the IC interface surface and the heatsink interface that is the sum of the plurality of TE elements.

14. The fixture of claim 13 wherein each TE element has thermal interface surfaces that progressively increase in size from the IC interface surface to the piston.

15. The fixture of claim 8 further comprising:
an environmental chamber surrounding the fixture having a port for the electrical interface; and,
a focused beam window overlying the IC die.

16. The fixture of claim 15 wherein the environmental chamber has a gas ingress port and a gas egress port.

17. The fixture of claim 8 further comprising:
a focused beam source selected from a group consisting of charged beam sources including a focused ion beam (FIB), scanning electron microscope (SEM), and E-beam, and a laser scanning microscope (LSM).

18. The fixture of claim 9 wherein each jaw cavity has a top surface shielding a charged beam from fields generated by current flow through the TE elements.

19. The fixture of claim 8 wherein the IC interface surfaces have a temperature of less than −20° C.

20. The fixture of claim 10 wherein first jaw IC interface surface has a first coefficient of temperature expansion, and the second jaw IC interface surface has the first coefficient of temperature expansion.
